(19) United States
(12) Patent Application Publication
(10) Pub. No.: US 2008/0073773 A1
(43) Pub. Date: Mar. 27, 2008

(54) ELECTRONIC DEVICE AND PRODUCTION METHOD

(75) Inventors: Erwin Huber, Muenchen (DE); Ralf Otremba, Kaufbeuren (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Nuebiberg (DE)

(21) Appl. No.: 11/859,456

(22) Filed: Sep. 21, 2007

(30) Foreign Application Priority Data
Sep. 22, 2006 (DE) 10 2006 044 690.9

(51) Int. Cl. H01L 23/48; H01L 21/56

(52) U.S. Cl. 257/690; 438/127; 257/E23.01; 257/E21.502

(57) ABSTRACT

An electronic device and production method is disclosed. One embodiment provides an integrated component, a housing body, and an electrically conductive first layer region arranged outside the housing body.

### CROSS-REFERENCE TO RELATED APPLICATIONS

This Utility Patent Application claims priority to German Patent Application No. DE 10 2006 044 690.9 filed on Sep. 22, 2006, which is incorporated herein by reference.

### BACKGROUND

The invention relates to an electronic device containing at least one integrated component. The integrated component contains one circuit element or a multiplicity of circuit elements, alternatively or additionally also sensor elements or other elements. The circuit elements used are in one embodiment semiconductor circuit elements, e.g., transistors, diodes, thyristors.

Integrated components are protected against ambient influences by a housing body. Consequently, the device is intended to be able to be provided with the housing body in a simple manner, wherein connection devices that form external connections of the device are to be provided.

There is a need for a simply constructed device which in particular is small and can be produced in a simple manner. Moreover, there is a need for a simple production method for a device. Elevated requirements are imposed particularly in the case of power devices.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIGS. 1A to 1D illustrate a first exemplary embodiment for the production of a device using bonding wires.

FIGS. 2A and 2B illustrate a second exemplary embodiment for the production of a device using a flip-chip method.

FIGS. 3A to 3C illustrate a third exemplary embodiment for the production of a device, wherein an inner redistribution wiring is simultaneously produced.

FIGS. 4A to 4D illustrate a fourth exemplary embodiment for the production of a device, wherein a connection curved away from the housing body is produced.

FIGS. 5A and 5B illustrate a fifth exemplary embodiment for the production of a device, wherein a connection curved away from the housing body is likewise produced.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One embodiment provides an electronic device, including:
an integrated component,
a housing body,
and an electrically conductive first layer region arranged outside the housing body.

Moreover, another embodiment provides a method including the following processes:
arrangement of an integrated component at an electrically conductive first layer,
application of a housing material to the component and/or to the first layer,
patterning of the first layer with production of layer regions after the application of the housing material.

The first layer region discussed, or the first layer can have two planar interfaces arranged parallel to one another. A homogeneous material of the layer region or partial layers of a layer stack which lie parallel to the interfaces can be arranged between the interfaces. The layer region or the interfaces can in particular also lie parallel to an outer area of the housing body, in particular to a main area, i.e. an area that is very large in comparison with lateral areas.

In one embodiment, the layer region can lie completely outside the housing body. Thus, in one embodiment, an interface of the layer region can lie in a plane or at a distance from a plane in which an outer area of the housing body lies; in one embodiment, the outer area and that interface of the layer region which lies closest to the housing body can face one another.

In another embodiment, the layer region can contain copper or a copper alloy, or include copper or a copper alloy containing at least 50 atomic percent or at least 80 atomic percent of copper. The layer region can thus form a device connection having a one embodimently good electrical conductivity.

In a next embodiment, an electrically conductive second layer or a second layer stack can be arranged between the first layer region and the component or between the first layer region and a connecting device arranged in the housing body, which connecting device leads to the component, for example. The second layer or the second layer stack can also be situated completely outside the housing body. This can be attributed for example to the fact that the two layer regions were patterned simultaneously after the housing body was arranged at a layer stack containing at least two layers from which the first layer region and the second layer region were produced for example using only one mask.

In one embodiment, the second layer can contain tin. In one embodiment, copper-tin alloys or silver-tin alloys are very well suited to diffusion bonding. The diffusion bonding has the effect that at a comparatively low temperature, for example of less than 200° C., a connection can be produced which is still temperature-resistant even at a comparatively high temperature of greater than 400° C., for example.

The connecting device arranged in the housing body can be a bonding wire. The bonding wire is preferably arranged at the second layer or at the second layer stack. As an alternative, the device arranged in the housing body can be a solder ball or a flip-chip connection, for example a copper pillar or copper bump.

Furthermore, the device can include or contain a further layer region. The further layer region includes the same material as the first layer region, wherein the further layer region can also be arranged completely outside the housing body. In one embodiment, the further layer region can be arranged in the same layer as the first layer region, wherein the two layer regions can be electrically insulated from one another, however.

In one embodiment, the component can be arranged at the first layer region, wherein a connecting device arranged in the housing body, in one embodiment a bonding wire or a contact clip, can lead from the component to the further layer region. In this embodiment, a contact clip is more rigid than a bonding wire and has a better heat conducting function, for example also as a cooling plate.

A first connecting device arranged in the housing body can lead from the component to the first layer region and a second connecting device arranged in the housing body can lead from the component to the further layer region. These two connecting devices can be, in one embodiment, bonding wires and/or contact clips.

The housing body can be arranged laterally with respect to the first layer region or even laterally adjoin the first layer region. Consequently, the first layer region then projects from the housing body, preferably with more than 30 or with more than 40 percent of its volume. The projecting defines a spacing with which the device can be arranged on a carrier, e.g., on a printed circuit board. The anchoring of the layer region is increased because the housing body is also arranged laterally with respect to the layer region.

the device can include or contain a further layer region composed of the same material as the first layer region. The housing body can also be arranged laterally with respect to the further layer region or laterally adjoin the further layer region. The further layer region can also project from the housing body. The first layer region and the second layer region can then be arranged in the same layer, but electrically insulated from one another.

In one embodiment, a region in which material of the housing body is arranged can thus lie between the first layer region and the further layer region.

The component can be connected to the first layer region, wherein a connecting device arranged in the housing body, in one embodiment a bonding wire or a contact clip, can lead from the component to the further layer region. A connecting device arranged in the housing can lead from the component to the first layer region and a second connecting device arranged in the housing body can lead from the component to the further layer region, wherein the connecting devices can again be for example elongated, e.g., bonding wires or contact clips etc.

In another embodiment, the device can contain a redistribution wiring device, which can contain the same material as the first layer region or can include the same material, wherein the redistribution wiring device is preferably electrically insulated from the first layer region although the redistribution wiring device is preferably situated in the same layer as the first layer region. However, the redistribution wiring device can have a smaller layer thickness than the layer region, wherein the layer thickness of the redistribution wiring device can preferably be at least 30 percent smaller than the layer thickness of the first layer region. This measure ensures that a spacing for electrical insulation is produced between the redistribution wiring device and a carrier device onto which the device is mounted, for example a printed circuit board.

Furthermore, the integrated component or a further integrated component can be arranged at the redistribution wiring device. In one or more embodiments, at least one connecting device arranged within the housing body, in one embodiment an elongated connecting device, such as e.g., a bonding wire or a contact clip, can be arranged at the redistribution wiring device.

In one embodiment, that side of the redistribution wiring device which is remote from the housing body can terminate with the nearest outer area of the housing body or even be recessed into the housing body with respect to the nearest outer area of the housing body in order to further increase the spacing with respect to a carrier plate onto which the component is mounted.

The device can also be formed in such a way that the first layer region or a second layer region having the same mentioned features as the first layer region is arranged in two layer elements. The two layer elements are partial layers of the layer region which are arranged parallel to one another. The two layer elements touch one another at a boundary zone. Laterally with respect to the boundary zone, the layer elements are arranged with a lateral offset in relation to one another, in one embodiment at mutually opposite edges of the boundary zone. To put it another way, a device connection curved away from the housing body arises. Such a connection is particularly well suited to compensating for mechanical stresses that take effect transversely with respect to the housing body. The curved connection acts in a similar manner to a leaf spring.

In one embodiment, the component can be arranged directly at the curved layer region, preferably using flip-chip technology.

The device can also include or contain at least one further layer region having the same mentioned features as the first layer region or as the curved layer region. The two layer regions are preferably electrically insulated from one another, nor is any material of the housing body situated between these two layer regions.

In another embodiment, the device can contain at least one curved layer region and an inner redistribution wiring device which does not form an external connection of the device.

The component can be, in one embodiment, a power component. In one embodiment, the power component can be a vertical power transistor. In a vertical power transistor, the electrons flow from the component front side (e.g., source) to the component rear side (e.g., drain), or vice versa. The conduction resistance of the power transistor can be significantly reduced by using a whole-area electrical contact of a component side, in one embodiment of the component rear side, with the directly underlying carrier plate. Power transistors can switch large switching voltages, for example switching voltages of greater than 10 volts, greater than 40 volts or even greater than 100 volts. The currents switched through the device are for example within the range of 1 ampere to 100 amperes or more. The powers can be for example within the range of 1 watt to 5 watts.

The integrated component can have for example at least one dimensioning which is less than 5 mm² (square millimeters). In one embodiment, the size of the area of the chip can be within the range of 1 mm² to 25 mm². By contrast, the size of the area of the device can preferably be within the range of 10 mm² to 100 mm². An area adaptation from the comparatively small chip area to a larger mounting area can thus be performed on account of the layer regions. In this context, the enlargement of a footprint will also be mentioned, which is explained in more detail below.

Moreover, the abovementioned method for producing an electronic device is specified. By way of example, a whole-area planarization is not necessary in this method. The first layer can have a uniform layer thickness prior to the arrangement of the housing body and can be severed in terms of its entire layer thickness during the patterning. Accordingly, only one patterning process is then required.

Moreover, a second layer arranged between the component and the first layer can be concomitantly patterned during the patterning. The second layer contains a different material than the first layer or includes a different material than the first layer. Thus, only one mask need be used for the patterning of the two layers. By way of example, the second layer is a protective layer for protecting the first layer or a layer to which connecting devices, e.g., bonding wires, within the device can be fixed better than to the first layer.

In another embodiment, a first patterning of the layer can also be carried out prior to the arrangement of the housing body, wherein patterning is effected at the side at which the housing body is then arranged. The patterning of the layer after the arrangement of the housing body is then a second patterning. The first patterning of the layer can preferably be carried out into a depth which is smaller than the layer thickness of the first layer. This procedure affords new application possibilities, such as, for example, an inner redistribution wiring produced simultaneously or a curved connection region. Moreover, what can be achieved by using this measure is that the housing body also laterally encompasses the connection devices or layer regions, such that the housing body can be anchored better.

The abovementioned measures enable integrated circuits or chips to be packaged cost-effectively, flexibly and in a standardizable manner. In one embodiment, it is thus also possible to package power transistors in the chip scale package (CSP) standard. On account of a redistribution wiring realized by the layer regions, the footprint of the device is not dependent on the chip size, such that the footprint can be adapted to a standardized or predetermined size. By using the CSP mounting proposed, in one embodiment, a power CSP mounting, in one embodiment advantages such as high flexibility of TSLP housings (Thin Small Leadless Package) are combined with cost advantages. In this case, the first layer is used as a sacrificial substrate for producing the footprint in order to avoid complicated redistribution wirings in the housing. Therefore, the first layer serves not only as a chip carrier during mounting but also as a basis for a flexible footprint. In this case, the anchoring of the footprint in the molding compound can be produced by using an additional etching process prior to the die bonding process with undercuts in the carrier film or first layer.

Insofar as “can” is used in the description, both the possibility and the actual technical realization are meant. The exemplary embodiments and embodiments explained are not intended to restrict the scope of protection of the invention, but rather are intended to serve only for elucidation purposes.

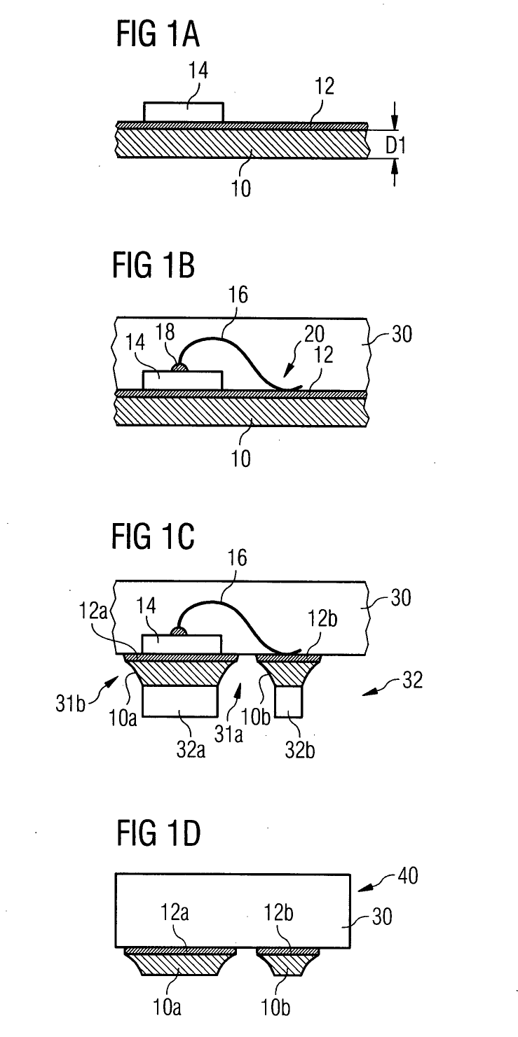

FIGS. 1A to 1D illustrate an embodiment for the production of a device. In this case, an unpatterned carrier layer 10, which can also be referred to as a metal film, is taken as a starting point. The carrier layer 10 is electrically conductive and has for example a thickness D1 within the range of 100 micrometers to 300 micrometers. By way of example, the carrier layer 10 is composed completely of copper, of a copper alloy having a high proportion of copper, for example greater than 80 atomic percent, or of a nickel-iron alloy, or of some other suitable electrically conductive material.

An optional electrically conductive layer 12 is situated on the carrier layer 10. By way of example, the optional carrier layer 12 improves the bondability of bonding wires in the case of a carrier layer 10 composed of copper. The layer 12 has for example a thickness within the range of 0.5 micrometer to 3 micrometers. Suitable materials for the layer 12 are for example aluminum, nickel, palladium, gold, silver, or layer stacks composed of the materials. In the exemplary embodiment, the layer 12 is applied to the carrier layer 10 over the whole area, such that no further patterning of the layer 12 is required prior to the application of a housing body, see FIG. 1B, housing body 30. The layer 12 can also be patterned or be applied in patterned fashion.

An integrated component or a chip 14 is fixed on the carrier layer 10 or on the optional layer 12, for example by soldering with a soft solder, by adhesive bonding with a conductive adhesive, or preferably by diffusion bonding. In the case of diffusion bonding, a layer which can be bonded directly onto the copper of the carrier layer 10 using a thin layer of tin is arranged for example at the rear side of the chip 14. As an alternative, a diffusion solder layer (AuSn, AgSn, CuSn) is formed both at the chip 14 and only at the carrier layer 10. Other material combinations which form intermetallic phases are likewise used, e.g., SnAg.

The chip 14 can contain a vertical circuit element, in one embodiment one or a plurality of vertical power transistors connected in parallel, or else lateral switching elements. Typically, a multiplicity of circuit elements are connected in parallel for power components.

As is illustrated in FIG. 1B, bonding wires 16 are subsequently bonded from the chip 14 onto the carrier layer 10 or the layer 12. Only one chip 14 with one bonding wire 16 is illustrated in the present example, for illustrative reasons. Typically, however, a plurality of bonding wires are bonded. If e.g., the chip contains only one vertical power transistor, e.g., two bonding wires connect the front side of the chip to the carrier layer 10 in order for example to connect “source” and “gate” (control connection) on the chip front side of the power transistor, while the drain is connected via the chip rear side.

A plurality of chips 14 (not illustrated) can also be arranged on the carrier layer 10. By way of example, the method can be carried out for four to six components simultaneously at the carrier layer 10. Thus, a bonding wire 16 is arranged at a front side, at which a control connection of a semiconductor component is arranged, the bonding wire being fixed to the chip 14 at a bonding location 18, in one embodiment a bonding pad. The bonding wire 16 is additionally fixed to a bonding location 20 situated at the layer 12. Instead of bonding wires or at different locations than bonding wires, metal clips can also be used, for example composed of copper, which enable greater heat conduction and can also transport higher currents than bonding wires. By way of example, diffusion bonding can again be used for fixing the metal clips.

After the connection of the chip 14 or of the further chips, a housing body 30 is produced, for example by pressing, potting, screen printing or similar methods. The housing body 30, without further insulating measures, includes e.g., an electrically insulating material, for example an epoxy-based material, in one embodiment epoxy resin.

As is illustrated in FIG. 1C, after the formation of the housing body 30, a resist layer 32 is applied, in one embodiment composed of photoresist, or else a hard mask composed of some other suitable material. The resist layer 32 is patterned and developed with the aid of a photolithographic method. A wet-chemical or dry-chemical etching process is subsequently carried out, wherein cutouts 31a and 31b are etched into the carrier layer 10 and into the optionally present layer 12. In this case, non-etched regions of the carrier layer 10 are covered by resist regions 32a and 32b. Contact regions 10a, in the exemplary embodiment for the rear side of the chip 14, and 10b, in the exemplary embodiment for the connection of the control region of a switching element, thus arise.

As is illustrated in FIG. 1D, the jointly fabricated devices are then singulated, wherein a device 40 arises. Elements that lie within the housing body 30 are not illustrated in FIG. 1D. If appropriate, still further production stages, in one embodiment test processes, laser markings, etc., lie between the production stage illustrated in FIG. 1C and the production stage illustrated in FIG. 1D. In an alternative variant, the method processes explained with reference to FIGS. 1A to 1D are performed only for an individual device 40.

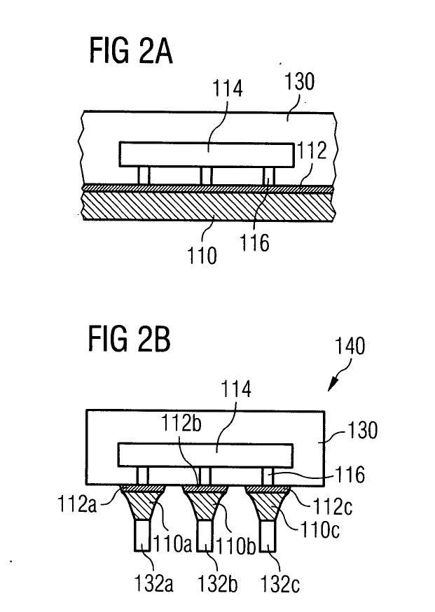

FIGS. 2A and 2B illustrate a second exemplary embodiment for the production of a device using a flip-chip method. A carrier layer 110 is used, on which a layer 112 is optionally applied. With regard to the carrier layer 110 and the layer 112, reference is made to the explanations concerning the carrier layer 10 and concerning the layer 12, respectively. A chip 114 is applied to the as yet unetched carrier layer 110 or to the as yet unpatterned layer 112 using flip-chip technology. Solder balls 116, for example, are used in this case. As an alternative, diffusion bonding can be used, for example if copper projections are formed at the chip 114. Further alternative or additional fixing or connection possibilities can be used, in one embodiment bonding wires.

The method explained with reference to FIG. 2A can also be carried out simultaneously for a plurality of chips 114, for example for six to ten chips 114. After the fixing and connection of the chips 114, a housing body 130 is produced at the layer 112 or directly at the carrier layer 110. With regard to the production of the housing body 130, reference is made to the housing body 30.

As is illustrated in FIG. 2B, after the production of the housing body 130, a mask is produced on the carrier layer 110, for example using a resist layer 132, which is patterned with the aid of a photolithographic method, wherein resist regions 132a, 132b and 132c are produced. The carrier layer 110 is then patterned with the aid of a wet-chemical or dry-chemical etching method, wherein layer regions 110a, 110b and 110c arise which are electrically insulated from one another. If a layer 112 is present, then the latter is concomitantly patterned simultaneously, i.e. using the resist regions 132a to 132c, wherein a two-stage etching method is also used, if appropriate.

Further production processes are subsequently carried out, such as testing, laser marking, etc. Afterward, the devices are singulated, wherein a device 140 arises. As an alternative, however, the method explained with reference to FIGS. 2A and 2B is also performed for an individual device 140.

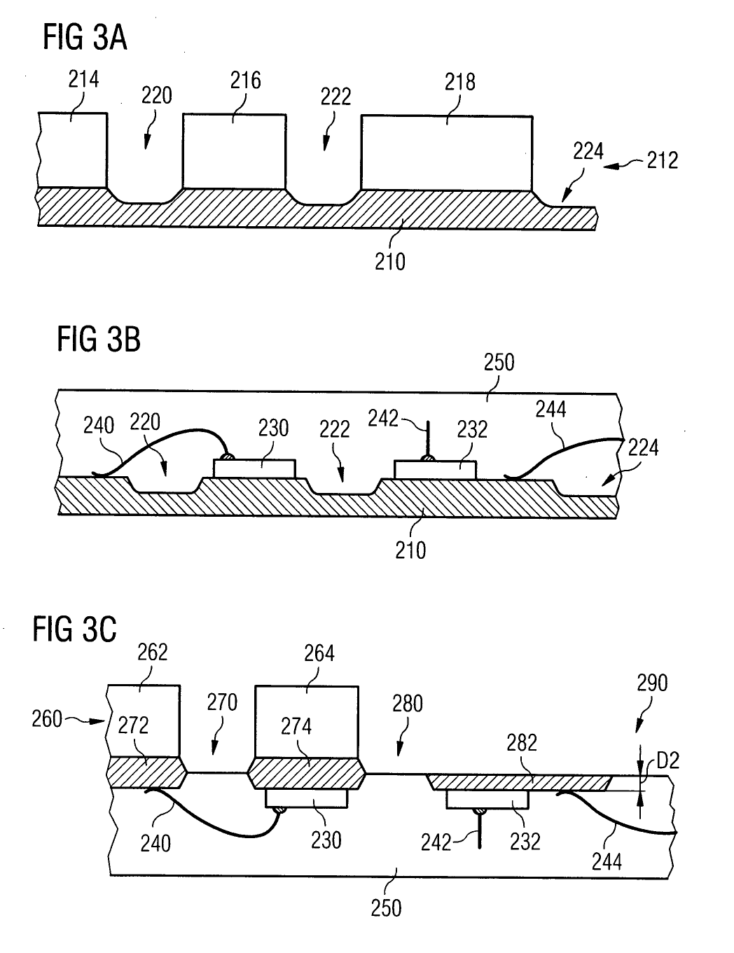

FIGS. 3A to 3C illustrate a third exemplary embodiment for the production of a device, wherein an inner redistribution wiring is simultaneously produced. A carrier layer 210 having a uniform layer thickness once again serves as a starting point, the statements made concerning the carrier layer 10 applying to the carrier layer 210. A mask is applied to the carrier layer 210, for example with the aid of a resist layer 212. The resist layer 212 is patterned by using a photolithographic method by selective irradiation or exposure and subsequent development, wherein resist regions 214, 216 and 218 arise, between which there are cutouts. With the aid of a wet-chemical or dry-chemical etching method, cutouts 220, 222 and 224 and also further cutouts (not illustrated) are etched into the carrier layer 210. The etching operation is carried out in wet-chemical or dry-chemical fashion and stopped for example when the cutouts 220 to 224 have a depth corresponding approximately to half the layer thickness of the carrier layer 210. As an alternative, the procedure stops in a range of +10 percent and −10 percent around half the layer thickness.

As is illustrated in FIG. 3B, after the production of the cutouts 220, 222, 224 and the removal of the resist regions 214, 216 and 218, chips 230, 232 and also further chips (not illustrated) are applied to the carrier layer 210 or an optional layer between the cutouts 220, 222, 224 which is such that it corresponds to the layer 12. In the exemplary embodiment, two chips 230, 232, for example a switching chip and a drive circuit, are used per device. In other exemplary embodiments, however, only one chip is used per device.

The chips 230, 232 are applied by using the same method as explained above for the chip 14. In this case, the chips 230, 232 are arranged between the cutouts 220, 222, 224, i.e. on as yet unthinned regions of the carrier layer 210.

Afterward, bonding wires 240, 242 are connected to the components 230, 232. The bonding wires lead for example directly to as yet unthinned regions of the copper layer 110. The bonding wire 240 leads to an as yet unthinned region which lies on the other side of the cutout 220 from the chip 230. The bonding wire 242 leads into the sheet plane or out of the sheet plane likewise to a contact region that is separated by the cutout 220 from the contact region to which the chip 232 is fixed. A bonding wire 244 rests with one end at the same contact region to which the chip 232 is also fixed. Instead of the bonding wires or in addition to the bonding wires 240 to 244, contact clips or other connecting devices can also be used.

After the connection of the chips 230, 232 with the aid of the bonding wires 240 to 244, a housing body 250 is produced, reference being made to the production of the housing body 30 that has already been described. By way of example, the housing body 250 is produced in a molding method.

As is illustrated in FIG. 3C, the carrier layer 210 together with housing body 250 is turned over, for example, in order subsequently to produce a further mask, for example with the aid of a resist layer 260. A hard mask is produced with the aid of a resist layer. The resist layer 260 is applied on the as yet unpatterned side of the carrier layer 210, selectively irradiated or exposed and developed, wherein resist regions 262 and 264 arise. The resist region 264 is produced at a region of the carrier layer 210 at which the resist layer 216 was located. The resist region 262 lies at a region of the carrier layer 210 at which the resist region 214 was located. In the resist layer 260, however, there is no resist region arranged at the region of the carrier layer 210 at which the resist layer 214 was arranged. In this way, an internal redistribution wiring 282 can be produced, as explained below.

With the aid of a wet-chemical or dry-chemical method, the carrier layer 210 is also etched selectively with respect to the mask 260 from the other side until cutouts 270 have been produced which reach through the layer thickness of the carrier layer 210 that remained in the course of the first patterning. Two contact regions 272 and 274 that are separated from one another arise laterally with respect to the cutout 270. In this case, the contact region 274 serves for the connection of the rear side of the chip 230. A cutout 280 thins a redistribution wiring region 282, at which the chip 232 and the bonding wire 244 are arranged. The redistribution wiring region 282 has a layer thickness D2 and serves for internal interconnect routing in the device that arises, that is to say that it itself does not constitute a connection toward the outside.

The resist regions 262 and 264 are removed after the etching. The devices are, if appropriate, tested, marked etc. The devices are subsequently singulated, wherein a device 290 also arises.

In other exemplary embodiments, the chips 230, 232 are applied using flip-chip technology, for example, wherein for example an inner redistribution wiring 282 is additionally produced.

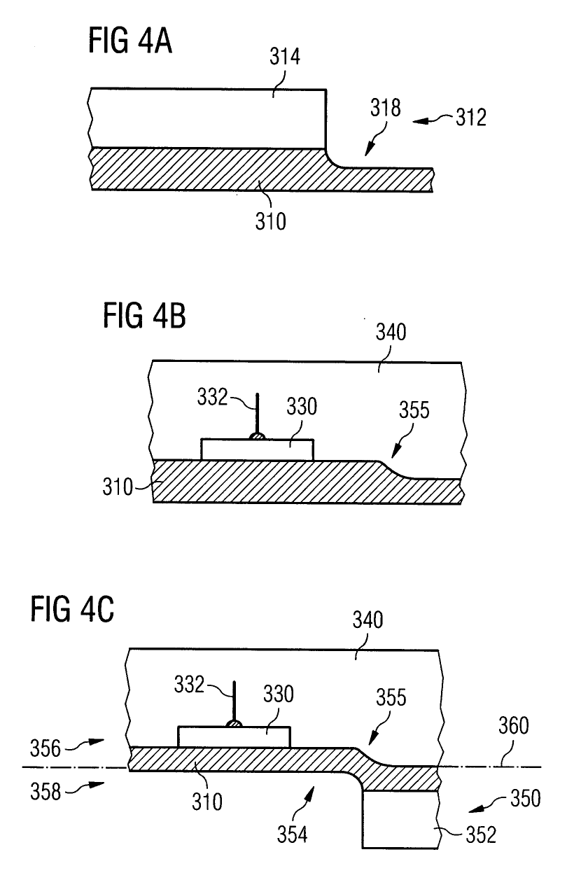

FIGS. 4A to 4D illustrate a fourth exemplary embodiment for the production of a device, wherein a connection curved away from a housing body 340 illustrated in FIG. 4C is produced. As is illustrated in FIG. 4A, a carrier layer 310 once again serves as a starting point, to which the statements made concerning the carrier layer 10 apply. Optionally, a layer corresponding to the layer 12 is also arranged on the carrier layer 310. A mask is applied to the as yet unthinned carrier layer 310 or to a layer corresponding to the layer 12, for example using a resist layer 312. The resist layer is selectively irradiated and developed, wherein a resist region 314, for example, is produced. With the aid of a wet-chemical or dry-chemical etching method, the carrier layer 310 is patterned, if appropriate also the layer which is present on the carrier layer 310 and which corresponds to the layer 12. Cutouts 318 arise, the bottom of which ends in each case in the carrier layer 310 because the carrier layer 310, during this first patterning, is patterned only in a partial layer but not in terms of its entire layer thickness.

As is illustrated in FIG. 4B, a chip 330 is subsequently arranged on an as yet unthinned region of the carrier layer 310, in one embodiment using flip-chip technology or with the aid of die bonding. Afterward, bonding wires 332 are optionally fixed to the chip 330, which bonding wires lead e.g., to other chips or to other external connections.

After the fixing of the chip 330, a housing body 340 is produced, to which the statements made concerning the housing body 30 apply. After the production of the housing body 340, as illustrated in FIG. 4C, a further mask is applied to the as yet unpatterned side of the carrier layer 310, for example with the aid of a resist layer 350. The resist layer 350 is patterned by using a lithographic method, wherein a resist region 352 is produced, which lies at a region at which no resist region 314 was located during the first patterning. With the aid of a wet-chemical or dry-chemical etching method, the carrier layer 310 is thinned, but only as far as approximately half the layer thickness of the carrier layer 110, as also during the patterning process explained with reference to FIG. 4A. It is not so essential that etching is in each case effected half way. It suffices for etching to be effected during the second etching until the carrier layer is “singulated” into individual regions, i.e. contact regions, redistribution wiring regions, etc. In one embodiment, a cutout 354 arises at the opposite side of the carrier layer 310 to the chip 330. Moreover, a curved section 355 that is curved away from the housing body 340 arises in the carrier layer 310. The resist region 352 is subsequently removed.

Consequently, the carrier layer 310 contains, in the region of the chip 330, a layer element 356 near the chip 330, and a layer element 358 remote from the chip 330. At a broken line 360, the two layer elements 356 and 358 adjoin one another in the curved section 355, in one embodiment at an inherently homogeneous material region.

As is illustrated in FIG. 4D, a further mask is arranged at that side of the carrier layer 310 which has already been patterned with the aid of the resist layer 350, in one embodiment with the aid of a resist layer 370, which is patterned with the aid of a photolithographic method, wherein resist regions 372 and 374 are produced. The resist region 372 also lies in a zone in which the resist region 352 was located, but extends nearer toward the chip 330. The resist region 374 additionally covers a region that was not covered by the developed resist layer 350, such that a redistribution wiring 380 is covered here. Afterward, a cutout 376 is etched with the aid of a wet-chemical or dry-chemical etching method, wherein the redistribution wiring 380 is electrically insulated from a connection region 378 with the curved section 355.

The resist regions 374, 372 are removed and, if appropriate, test processes, marking processes, etc. are carried out. A plurality of devices that were produced simultaneously at the carrier layer 310 are then singulated, see device 390.

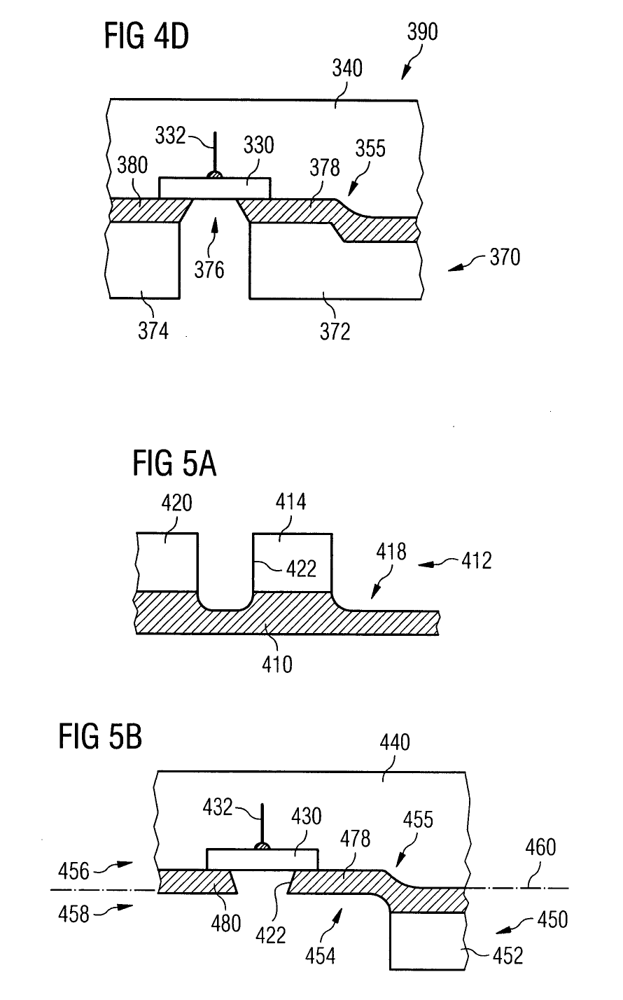

In another exemplary embodiment, in accordance with FIGS. 5A and 5B, a cutout 422 is produced during the first patterning process. This is indicated by resist regions 314, 320 and the cutout 422 in FIG. 5A. For the rest, the method processes explained with reference to FIGS. 4B and 4C are carried out. Identical elements are provided with reference symbols whose value is increased by the value 100, e.g., chip 430 in comparison with chip 330. A redistribution wiring 480 and a curved connection region 478 also arise without a third patterning process.

In other exemplary embodiments, at the chip 330 or 430 there is both on the left and on the right in each case a connection 378 with curved region 355, and, if appropriate, further curved connections. The method processes illustrated in FIGS. 4A to 5B can be carried out in one embodiment if only one chip 330 is used per device 390, or if a plurality of chips are used, for example two chips, as in the case of switching elements connected as a half-bridge circuit, or four chips, as in the case of switching elements connected as a full-bridge circuit. Drive circuits can also optionally be contained in a device 390, 490 in addition to a chip.

The methods explained with reference to FIGS. 1A to 5B are suitable for power components, in one embodiment.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An electronic device, comprising:
an integrated component;
a housing body; and
an electrically conductive first layer region arranged outside the housing body.

2. The device of claim 1, comprising wherein the first layer region is arranged completely outside the housing body.

3. The device of claim 2, comprising:
wherein the first layer region contains copper or a copper alloy; or
wherein the first layer region comprises copper or a copper alloy containing at least 50 atomic percent of copper.

4. The device of claim 2, comprising wherein a second layer or a layer stack lying completely outside the housing body is arranged between the first layer region and the component or between the first layer region and a connecting device arranged in the housing body.

5. The device of claim 4, wherein the second layer comprises a different material than the first layer region or contains a different material consisting of a copper-tin alloy or a copper-gold-tin alloy or a silver-tin alloy or a silver-gold-tin alloy.

6. The device of claim 4, comprising:
wherein the connecting device arranged in the housing body is a bonding wire, arranged at the second layer or at the layer stack; or
wherein the connecting device arranged in the housing body is a solder ball or a flip-chip connection.

7. The device of claim 2, comprising:
wherein the device comprises or contains a further layer region containing the same material as the first layer region; and
wherein the further layer region is arranged in the same layer as the first layer region.

8. The device of claim 7, comprising:
wherein the component is arranged at the first layer region, and wherein a connecting device arranged in the housing body, a bonding wire or a contact clip, leads from the component to the further layer region; or
wherein a first connecting device arranged in the housing body leads from the component to the first layer region and a second connecting device arranged in the housing body leads from the component to the further layer region, wherein the first connecting device and the second connecting device are preferably a bonding wire or a contact clip.

9. The device of claim 1, comprising:
wherein the housing body is arranged laterally with respect to the first layer region or laterally adjoins the first layer region; and/or
wherein the first layer region projects from the housing body, with more than 30 percent or with more than 40 percent of a volume.

10. The device of claim 9, wherein the device comprises or contains a further layer region composed of the same material as the first layer region;
wherein the housing body is also arranged laterally with respect to the further layer region or laterally adjoins the further layer region; and
wherein the further layer region projects from the housing body; and
wherein the further layer region is preferably arranged in the same layer as the first layer region.

11. The device of claim 10, comprising wherein a region in which material of the housing body is arranged lies between the first layer region and the second layer region.

12. The device of claim 10, comprising:
wherein the component is connected to the first layer region, and wherein a connecting device arranged in the housing body, a bonding wire or a contact clip, leads from the component to the further layer region; or
wherein a first connecting device arranged in the housing body leads from the component to the first layer region and a second connecting device arranged in the housing body leads from the component to the further layer region,
wherein the first connecting device and the second connecting device are a bonding wire or contact clip.

13. The device, of claim 10, comprising wherein the device contains a redistribution wiring device composed of the same material as the first layer region, preferably a redistribution wiring device that is electrically insulated from the first layer region.

14. The device of claim 13, comprising:
wherein the redistribution wiring device and the first layer region are arranged in one layer; and
wherein the redistribution wiring device has a smaller layer thickness than the first layer region that is at least 30 percent smaller.

15. The device of claim 13, comprising:
wherein the integrated component or a further integrated component is arranged at the redistribution wiring device; and/or
wherein at least one connecting device arranged within the housing body, in particular a bonding wire or a contact clip, is arranged at the redistribution wiring device.

16. The device of claim 13, comprising wherein that side of the redistribution wiring device which is remote from the housing body terminates with the nearest outer area of the housing body or is recessed into the nearest outer area of the housing body by at least 10 micrometers.

17. The device of claim 9, comprising wherein the first layer region or a second layer region having the same mentioned features as the first layer region is arranged in two layer elements of a layer; and
wherein the two layer elements adjoin one another in a first zone and, laterally with respect thereto, are arranged offset in relation to one another.

18. The device of claim 17, comprising wherein the component is arranged at the layer region containing the layer elements.

19. The device of claim 17, wherein the device comprises at least one further layer region having the same mentioned features as the first layer region or as the layer region having the layer elements; and
wherein the entire region between the first layer region and the layer region having the layer elements or between the two layer regions having the layer elements is free of material of the housing body.

20. The device of claim 17, wherein the device comprises or contains at least one redistribution wiring device; and
wherein the entire region between the layer region having the layer elements and the redistribution wiring device is free of material of the housing body.

21. The device of claim 17, comprising:
wherein the component is a power component having a switching power of greater than 1 watt, or
wherein the component is a vertical component.

22. The device of claim 17, comprising wherein the first layer region has etched lateral areas.

23. The device of claim 17, comprising wherein the first layer region has two planar interfaces lying essentially parallel to one another, wherein the interfaces are inclined at most by one degree or at most by three degrees with respect to one another.

24. The device of claim 17, comprising wherein only one layer composed of a different material than the material of the first layer region is arranged between the component and the first layer region.

25. The device of claim 17, comprising wherein a distance between that side of the component which faces the first layer region and that interface of the first layer region which faces the component is less than 10 micrometers or less than 5 micrometers.

26. The device of claim 17, comprising wherein the first layer region has a uniform layer thickness within the range of 100 micrometers to 300 micrometers.

27. The device of claim 17, comprising wherein the first layer region contains copper or a copper alloy, or wherein the first layer region comprises copper or a copper alloy containing at least 50 atomic percent or 80 atomic percent of copper.

28. A method for producing an electronic device, comprising:
arranging an integrated component at an electrically conductive first layer;
applying a housing material to the component and/or to the first layer; and
after the application of the housing material patterning of the first layer with production of layer regions.

29. The method of claim 28, comprising curing the housing material to form a housing body.

30. The method of claim 28, comprising:
wherein, during the patterning, the first layer is patterned in terms of its entire layer thickness; and
wherein the first layer preferably has a uniform layer thickness prior to the patterning.

31. The method of claim 30, comprising:
patterning of a second layer arranged between the component and the first layer after the arrangement of the housing body; and
wherein the second layer contains a different material or comprises a different material than the first layer.

32. The method of claim 31, comprising using the same mask for the patterning of the first layer and of the second layer.

33. The method of claim 28, comprising:
first patterning of the first layer prior to the arrangement of the housing body; and
wherein the patterning of the first layer after the arrangement of the housing body is a second patterning.

34. The method of claim 33, comprising carrying out the first patterning and the second patterning only into a depth which is smaller than the layer thickness of the first layer.

35. The method of claim 33, comprising:
during the first patterning and during the second patterning, at least one first layer region is in each case protected by a mask; and
wherein the first layer region preferably forms the outer connection of the device.

36. The method of claim 33, comprising:
covering, during the first patterning, at least one second layer region with a first mask; and
thinning the second layer region during the second patterning, preferably until the second layer region is separated from the first layer region; and
wherein the second layer region remains as redistribution wiring in the device.

37. The method of claim 33, comprising:
forming two layer elements of a first layer region by thinning the first layer from two different sides; and
forming a curved connection of the device.

38. The method of claim 37, comprising forming the two layer elements such that they adjoin one another in a first zone and, laterally with respect to the first zone, are laterally offset in relation to one another.

39. An electronic device, comprising:
an integrated component;
a housing body;
an electrically conductive first layer region arranged outside the housing body;
wherein the first layer region is arranged completely outside the housing body; and
wherein a second layer or a layer stack lying completely outside the housing body is arranged between the first layer region and the component or between the first layer region and a connecting device arranged in the housing body.

40. An electronic device, comprising:
an integrated component;
a housing body;
an electrically conductive first layer region arranged outside the housing body;
wherein the housing body is arranged laterally with respect to the first layer region or laterally adjoins the first layer region;
wherein the device contains a redistribution wiring device composed of the same material as the first layer region; and
wherein the redistribution wiring device and the first layer region are arranged in one layer; and
wherein the redistribution wiring device has a smaller layer thickness than the first layer region.

41. An electronic device, comprising:
an integrated component;
a housing body;
an electrically conductive first layer region arranged outside the housing body;
wherein the housing body is arranged laterally with respect to the first layer region or laterally adjoins the first layer region;
wherein the first layer region or a second layer region having the same mentioned features as the first layer region is arranged in two layer elements of a layer; and
wherein the two layer elements adjoin one another in a first zone and, laterally with respect thereto, are arranged offset in relation to one another.
